(19) United States
(12) Patent Application Publication
(10) Pub. No.: US 2019/0047272 A1
(43) Pub. Date: Feb. 14, 2019

(54) LAMINATED SHEET AND APPLICATION OF THE SAME

(71) Applicant: SOUTHERN TAIWAN UNIVERSITY OF SCIENCE AND TECHNOLOGY, Tainan City (TW)

(72) Inventors: Wen-Hai WU, Taipei City (TW); Jian-Ren HU, Tainan City (TW); Po-Kuei WU, Taichung City (TW)

(21) Appl. No.: 15/909,296

(22) Filed: Mar. 1, 2018

(30) Foreign Application Priority Data
Aug. 8, 2017 (TW) 106126668

(51) Int. Cl. B32B 27/36; B32B 27/08; C08J 5/18; H01L 31/048; H01L 33/56

(52) U.S. Cl. CPC B32B 27/36; B32B 27/08; C08J 5/18; H01L 31/0481; C08J 2365/04; B32B 2250/03; B32B 2307/412; B32B 2457/12; C08J 2367/02; H01L 33/56

(57) ABSTRACT

A laminated sheet includes a polymer layer selected from the group consisting of polyalkylene phthalate, polyalkylene isophthalate, polyalkylene terephthalate, and combinations thereof, and two poly(α,α,α′,α′-tetrafluoro-para-xylylene) layers respectively connected to two opposite surfaces of the polymer layer.

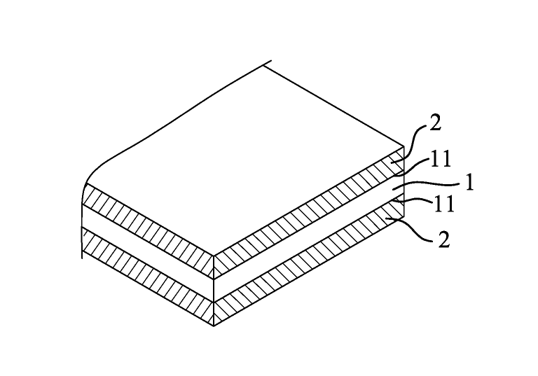

### CROSS-REFERENCE TO RELATED APPLICATION

This application claims priority of Taiwanese Patent Application No. 106126668, filed on Aug. 8, 2017.

### FIELD

The disclosure relates to a laminated sheet, and more particularly to a laminated sheet having poly(α,α,α′,α′-tetrafluoro-para-xylylene) layers. The disclosure also relates to a light-emitting device containing the laminated sheet.

### BACKGROUND

Taiwanese patent application publication No. 201422444 discloses a laminated structure and a light-emitting device including the laminated structure. The laminated structure includes a substrate having a surface, an intermediary layer provided on the surface of the substrate, and a poly(p-xylylene) film disposed on the intermediary layer. Examples of the substrate include a metal substrate, a semiconductor substrate, a glass substrate, a plastic substrate, etc. The plastic substrate may be made from polyimide, polyethylene terephthalate, polyethylene 2,6-naphthalate, polyethersulfone, polycarbonate, etc. The intermediary layer of the laminated structure is formed using a silane coupling agent, and is covalently bonded to the substrate and the poly(p-xylylene) film through Si—C bonds and Si—X bonds with X being either oxygen or nitrogen. Examples of the silane coupling agent include hexamethyldisiloxane and hexamethyldisilazane. Examples of the poly(p-xylylene) film include Parylene-C, Parylene-D, Parylene-N, and Parylene-F.

Although the intermediary layer of the laminated structure enables the poly(p-xylylene) film to have better adhesion with the substrate, hexamethyldisiloxane and hexamethyldisilazane used to form the intermediary layer exhibit poor thermal stability. When the laminated structure is placed or used under high temperature, defects such as air bubbles may occur between the poly(p-xylylene) film and the substrate.

A back plate made from the laminated structure is usually installed in a light-emitting device or a solar cell module as a protection against environmental damage caused by, e.g., ultraviolet (UV) light. Polymeric materials of the laminated structure might undergo discoloration (e.g., turning yellowish) and oxidization upon irradiation with UV light, causing the polymeric materials to become decomposed that might result in the loss-of-function of the solar cell module and the light-emitting device. Therefore, a back plate with anti-UV and anti-oxidation properties contributes significantly to enhancing the effectiveness and extending the life span of the solar cell module and the light-emitting device.

### SUMMARY

Therefore, an object of the disclosure is to provide a laminated sheet that can alleviate at least one of the drawbacks of the prior art.

According to the disclosure, a laminated sheet includes a polymer layer selected from the group consisting of polyalkylene phthalate, polyalkylene isophthalate, polyalkylene terephthalate, and combinations thereof, and two poly(α,α,α′,α′-tetrafluoro-para-xylylene) layers respectively connected to two opposite surfaces of the polymer layer.

### BRIEF DESCRIPTION OF THE DRAWINGS

Other features and advantages of the present disclosure will become apparent in the following detailed description of the embodiment with reference to the accompanying drawing, of which:

The Sole FIGURE is a fragmentary perspective view of an embodiment of a laminated sheet according to the present disclosure.

### DETAILED DESCRIPTION

Before the disclosure is described in greater detail, it should be noted that where considered appropriate, reference numerals or terminal portions of reference numerals have been repeated among the FIGURES to indicate corresponding or analogous elements, which may optionally have similar characteristics.

Referring to the Sole FIGURE, an embodiment of a laminated sheet of this disclosure includes polymer layer 1, and two poly (α,α,α′,α′-tetrafluoro-para-xylylene) layers 2 respectively connected to two opposite surfaces 11 of the polymer layer 1.

Examples of the polymer layer 1 include polyalkylene phthalate, polyalkylene isophthalate, polyalkylene terephthalate, and combinations thereof.

The polymer layer 1 is formed by polymerization of a reactant mixture that includes alkylene glycol and at least one of phthalic acid, isophthalic acid, terephthalic acid, dimethyl phthalate, dimethyl isophthalate, or dimethyl terephthalate.

In an embodiment of this disclosure, the polymer layer 1 is a polyalkylene terephthalate layer. In an example of this disclosure, the polymer layer 1 is a polyethylene terephthalate layer.

The alkylene glycol may be ethylene glycol.

Poly(α,α,α′,α′-tetrafluoro-para-xylylene) layer 2, also known as parylene HT or parylene AF4 layer, is formed from 1,1,2,2,9,9,10,10-octafluoro[2.2]paracyclophane using a well-known Gorham method. Briefly, the dimer 1,1,2,2,9,9,10,10-octafluoro[2.2]paracyclophane is vaporized at a temperature between 90° C. and 160° C., and then cracked to two reactive monomer groups at a temperature between 650° C. and 750° C., followed by chemical vapor deposition (CVD) procedure under a pressure ranging between 1 mTorr and 100 mTorr, and polymerization so as to form the poly((α,α,α′,α′-tetrafluoro-para-xylylene) layer 2 on the polymer layer 1.

The laminated sheet of this disclosure can be used as a back plate in a solar cell module. In an embodiment of the present disclosure, the solar cell module includes the laminated sheet and a solar cell connected to one of the poly(α,α,α′,α′-tetrafluoro-para-xylylene) layers 2. There is no special restriction on the types of solar cell, as the ones adopted in the past can be used. Since the laminated sheet of this disclosure has been proven to have good UV light stability, thermal stability and anti-oxidation property, the application of the laminated sheet in the solar cell module can enhance the effectiveness and extends the life span of the solar cell module.

The laminated sheet of this disclosure can also be used as a back plate in a light-emitting device. In an embodiment of the present disclosure, the light-emitting device include at least one of the laminated sheet and a light-emitting element connected to one of the poly (α,α,α′,α′-tetrafluoro-para-xylylene) layers 2 of the laminated sheet. In certain embodiments, the light-emitting device includes two of the laminated sheets, and the light-emitting element is located between the laminated sheets and connected to one of the poly(α,α,α′,α′-tetrafluoro-para-xylylene) layers 2 of each of the laminated sheets. There is no special restriction on the types of light-emitting element, as the ones adopted in the past can be used, e.g., an organic light-emitting diode. In addition, the number of the laminated sheet in the light-emitting device can be adjusted according to practical use. As mentioned above, since the laminated sheet of this disclosure has been proven to have good UV light stability, thermal stability and anti-oxidation property, the application of the laminated sheet in the light-emitting device can enhance the effectiveness and extends the life span of the light-emitting device.

The disclosure will be further described by way of the following examples. However, it should be understood that the following examples are solely intended for the purpose of illustration and should not be construed as limiting the disclosure in practice.

### EXAMPLES

### Example 1 (E1)

A laminated sheet of Example 1 (E1) of this disclosure includes a polyethylene terephthalate layer, and two poly(α,α,α′,α′-tetrafluoro-para-xylylene) layers respectively connected to two opposite surfaces of the polyethylene terephthalate layer.

The laminated sheet of E1 was made by the following steps. A polyethylene terephthalate (PET) layer (Manufacturer: Nan Ya Plastics Corporation; optoelectronic grade polyester film; 166% of glossiness, 3.7% of haziness, light transmittance rate of 88.7%, 100 μm of thickness) was disposed into a chamber of a deposition system. 14.5 μg of 1,1,2,2,9,9,10,10-octafluoro[2.2] paracyclophane was vaporized at 140° C. and cracked at 720° C. under 40 mTorr, followed by deposition and polymerization on the opposite surfaces of the polyethylene terephthalate layer for 120 minutes. Two layers of poly(α,α,α′,α′-tetrafluoro-para-xylylene), each having a thickness of 1277 nm, were thus respectively deposited on two opposite surfaces of the polyethylene terephthalate layer, thereby forming the laminated sheet of E1.

### Comparative Example 1 (CE1)

A polyethylene terephthalate layer (Manufacturer: Nan Ya Plastics Corporation; optoelectronic grade polyester film; 166% of glossiness, 3.7% of haziness, light transmittance rate of 88.7%, 100 μm of thickness) was provided as a sample of CE1.

### Comparative Example 2 (CE2)

A laminated sheet of Comparative Example 2 (CE2) includes a polyethylene terephthalate layer and two layers of poly(monochloro-p-xylylene), known as parylene C, respectively connected to two opposite surfaces of the polyethylene terephthalate layer.

The method for preparing the laminated sheet of CE2 includes the following steps. A polyethylene terephthalate (PET) layer (Manufacturer: Nan Ya Plastics Corporation; optoelectronic grade polyester film; 166% of glossiness, 3.7% of haziness, light transmittance rate of 88.7%, 100 μm of thickness) was disposed into a chamber of a deposition system. 3.5 g of monochloro-[2,2]paracyclophane was vaporized at 170° C. and cracked at 690° C. under 5 mTorr, followed by deposition and polymerization on the opposite surfaces of the polyethylene terephthalate layer for 80 minutes. Two layers of poly(monochloro-p-xylylene), each having a thickness of 1314 nm, were thus respectively deposited on two opposite surfaces of the polyethylene terephthalate layer, thereby forming the laminated sheet of CE2.

### Comparative Example 3 (CE3)

A laminated sheet of Comparative Example 3 (CE3) includes a polyethylene terephthalate layer and two layers of poly(p-xylylene), known as parylene N, respectively connected to two opposite surfaces of the polyethylene terephthalate layer.

The method for preparing the laminated sheet of CE3 includes the following steps. A polyethylene terephthalate (PET) layer (Manufacturer: Nan Ya Plastics Corporation; optoelectronic grade polyester film; 166% of glossiness, 3.7% of haziness, light transmittance rate of 88.7%, 100 μm of thickness) was disposed into a chamber of a deposition system. 7.09 g of [2.2] paracyclophane was vaporized at 160° C. and cracked at 650° C. under 55 mTorr, followed by deposition and polymerization on the opposite surfaces of the polyethylene terephthalate layer for 150 minutes. Two layers of poly(p-xylylene), each having a thickness of 1264 nm, were thus respectively deposited on two opposite surfaces of the polyethylene terephthalate layer, thereby forming the laminated sheet of CE3.

### Measurement of UV Light Stability:

Each of the laminated sheets of E1, CE2 and CE3 and the polyethylene terephthalate layer of CE1 was cut into a size of 4 cm×4 cm, forming four test samples. The test samples were placed into a box having a 2000 W UV light with a wavelength ranging from 300 nm to 500 nm. The distance between the UV light and the test samples was 5 cm, and the test samples were irradiated for 10 hours. The appearance and color changes of the test samples were observed visually.

The UV light stability of the test samples was measured by calculating the color difference of the test samples, before and after 10 hours of UV light irradiation, using a colorimeter (Manufacturer: An-Bomb Instruments Co., Ltd.; Model No.: NH310TW). The color difference value (ΔE) was calculated based on the coordinates of 1976 CIELAB color space, using the 1976 formula: [(ΔL) 2+(Δa)²+(Δb)²]^{1/2}, in that, ΔL is L2-L1, Δa is a2-a1, Δb is b2-b1. L1 and L2 respectively represent the coordinates of the color lightness of 1976 CIELAB color space, before and after UV light irradiation. The coordinates between red/magenta and green in 1976 CIELAB color space, before and after UV light irradiation, are respectively represented by a1 and a2, while b1 and b2 respectively represent the coordinates between yellow and blue in 1976 CIELAB color space, before and after UV light irradiation. The appearances and color changes, together with ΔL, Δa, Δb and ΔE values of each test samples, before and after 10 hours of UV light irradiation, are shown in Table 1. It is noted that the smaller Δb represents more difficulty for the test samples to undergo discoloration (e.g., turn yellowish).

TABLE 1

| | | | Comparative | | |
|---|---|---|---|---|---|
| | | | Example 1 | Comparative | Comparative |
| | | | (CE1) | Example 2 | Example 3 |
| | | | Polyethylene | (CE2) | (CE3) |
| | | Example 1 | terepthalate | Laminated | Laminated |
| | | Laminated sheet | layer | sheet | sheet |
| Appearance changes after 10 | | No distortion & | Curl | No | NO |
| hours of UV light irradiation | | discoloration | distortion, | distortion, | distortion, |
| | | | turn | turn | turn |
| | | | yellowish | yellowish | yellowish |
| 1976 CIELAB | L1 value | 91.97 | 93.61 | 93.21 | 93.25 |
| color space | a1 value | 0.94 | 0.70 | 0.67 | 1.07 |
| coordinates | b1 value | 2.97 | 2.21 | 2.38 | 2.23 |
| before UV light | | | | | |
| irradiation | | | | | |
| 1976 CIELAB | L2 value | 91.89 | 91.39 | 91.56 | 91.83 |
| color space | a2 value | 0.67 | 0.76 | 1.00 | 0.82 |
| coordinates | b2 value | 5.63 | 6.08 | 7.69 | 7.19 |
| after 10 hours of | | | | | |
| UV light | | | | | |
| irradiation | | | | | |
| 1976 CIELAB | ΔL value | −0.08 | −2.22 | −1.65 | −1.42 |
| color space | Δa value | −0.27 | 0.06 | 0.33 | −0.25 |
| coordinates | Δb value | 2.66 | 3.87 | 5.31 | 4.96 |
| differences | ΔE value | 2.68 | 4.46 | 5.57 | 5.17 |
| before and after | | | | | |
| UV light | | | | | |
| irradiation | | | | | |

### Measurement of Anti-Oxidation Property:

The test samples were subjected to the measurement of an area ratio of the C═O absorption peak at 1725 cm⁻¹, before and after 10 hours of UV light irradiation, using an infrared spectrophotometer (Manufacturer: PerkinElmer; Model No.: Spectrum One). The area ratio was obtained using a formula: (integrated area of the C═O absorption peak at 1725 cm⁻¹/sum of the integrated areas of all absorption peaks)×100%. The larger the area ratio variation of the C═O absorption peak at 1725 cm⁻¹ before and after 10 hours of UV irradiation, the higher the degree of oxidation of the polyethylene terephthalate layer of the test samples. The area ratio variation (%) of each of the test samples was calculated using a formula: [(area ratio of C═O absorption peak after 10 hours of UV light irradiation-area ratio of C═O absorption peak before UV light irradiation)/area ratio of C═O absorption peak before UV light irradiation]×100%, and is shown in Table 2.

TABLE 2

| | | Comparative | | Compar- |
|---|---|---|---|---|
| | | Example 1 | Comparative | ative |
| | | (CE1) | Example 2 | Example 3 |
| | Example 1 | Polyethylene | (CE2) | (CE3) |
| | Laminated | terepthalate | Laminated | Laminated |
| | sheet | layer | sheet | sheet |
| Area ratio of C═O | 3.67 | 7.06 | 3.94 | 6.27 |
| absorption peak | | | | |
| before UV light | | | | |
| irradiation (%) | | | | |
| Area ratio of C═O | 3.76 | 8.67 | 4.82 | 6.83 |
| absorption peak | | | | |
| after 10 hours of | | | | |
| UV light | | | | |
| irradiation (%) | | | | |
| Area ratio | 2.45 | 22.8 | 22.3 | 8.93 |
| variation of the | | | | |
| C═O absorption | | | | |
| peak before and | | | | |
| after UV light | | | | |
| irradiation (%) | | | | |

### Measurement of Thermal Stability:

Each of the test samples was subjected to thermogravimetric analysis before and after 10 hours of UV light irradiation to determine the onset temperature that each of the test samples starts to have mass change. The thermogravimetric analysis was conducted using Simultaneous Thermal Analyzer (Manufacturer: PerkinElmer; Model No.: STA6000) with temperature ranging from 50° C. to 650° C. and temperature rise rate of 15° C./min. The onset temperature for each of the test samples before and after 10 hours of UV light irradiation are shown in Table 3.

TABLE 3

| | | | Comparative | | |
|---|---|---|---|---|---|
| | | | Example 1 | Comparative | Comparative |
| | | Example 1 | (CE1) | Example 2 | Example 3 |
| | | (E1) | Polyethylene | (CE2) | (CE3) |
| | | Laminated | terephthalate | Laminated | Laminated |
| | | sheet | layer | sheet | sheet |
| Onset temperature | Before UV light | 413.85 | 414.78 | 414.19 | 417.47 |
| of | irradiation | | | | |
| termogravimetric | After 10 hours of | 417.88 | 410.85 | 412.19 | 415.10 |
| analaysis (° C.) | UV light | | | | |
| | irradiation | | | | |

Based on the experimental data in Tables 1, 2 and 3, in comparison with the polyalkylene terephthalate layer of CE1 and the laminated sheet of CE2 and CE3, the laminated sheet of E1 having poly(α,α,α′,α′-tetrafluoro-para-xylylene) layers 2 demonstrates a higher onset temperature of thermogravimetric analysis and no distortion, even after 10 hours of UV light irradiation. In addition, the laminated sheet of E1 showed no discoloration (e.g., turning yellowish) based on visual observation, and has the smallest Δb value among all the test samples. The results indicate that the laminated sheet of E1 has good UV light stability and thermal stability. Moreover, the good anti-oxidation property of the laminated sheet of E1 is proven by the relatively small area ratio variation of the C═O absorption peak before and after UV light irradiation.

In summary, by connecting poly (α,α,α′,α′-tetrafluoro-para-xylylene) layers 2 to the two opposite surfaces of the polymer layer 1, the laminated sheet of this disclosure is prevented from distortion, discoloration (e.g., turning yellowish), and/or oxidization by UV light irradiation. Since the laminated sheet has good thermal stability, ultraviolet light stability and anti-oxidation properties, the laminated sheet is therefore suitable to be installed as a back plate in the solar cell module and the light-emitting device. The application of the laminated sheet can thereby enhance the effectiveness and extends the life span of the solar cell module and the light-emitting device.

In an embodiment, the disclosure relates to a laminated sheet, comprising a polymer layer selected from the group consisting of polyalkylene phthalate, polyalkylene isophthalate, polyalkylene terephthalate, and combinations thereof; and two poly(α, α, α′, α′-tetrafluoro-para-xylylene) layers respectively connected to two opposite surfaces of the polymer layer.

In a further embodiment, the disclosure relates to at least one of the preceding embodiments, wherein the polymer layer of the laminated sheet is a polyalkylene terephthalate layer.

In a further embodiment, the disclosure relates to at least one of the preceding embodiments, wherein the polyalkylene terephthalate layer of the laminated sheet is a polyethylene terephthalate layer.

In a further embodiment, the disclosure relates to a solar cell module, comprising a laminated sheet including a polymer layer selected from the group consisting of polyalkylene phthalate, polyalkylene isophthalate, polyalkylene terephthalate, and combinations thereof, and two poly(α, α, α′, α′-tetrafluoro-para-xylylene) layers respectively connected to two opposite surfaces of the polymer layer; and a solar cell connected to one of the poly(α, α, α′, α′-tetrafluoro-para-xylylene) layers.

In a further embodiment, the disclosure relates to at least one of the preceding embodiments, wherein the polymer layer of the solar cell module is polyalkylene terephthalate layer.

In a further embodiment, the disclosure relates to at least one of the preceding embodiments, wherein the polyalkylene terephthalate layer of the solar cell module is a polyethylene terephthalate layer.

In a further embodiment, the disclosure relates to a light-emitting device, comprising at least one laminated sheet including a polymer layer selected from the group consisting of polyalkylene phthalate, polyalkylene isophthalate, polyalkylene terephthalate, and combinations thereof, and two poly(α, α, α′, α′-tetrafluoro-para-xylylene) layers respectively connected to two opposite surfaces of the polymer layer; and a light-emitting element connected to one of the poly(α, α, α′, α′-tetrafluoro-para-xylylene) layers of the laminated sheet.

In a further embodiment, the disclosure relates to at least one of the preceding embodiments, wherein the polymer layer of the light-emitting device is a polyalkylene terephthalate layer.

In a further embodiment, the disclosure relates to at least one of the preceding embodiments, wherein the polyalkylene terephthalate layer of the light-emitting device is a polyethylene terephthalate layer.

In a further embodiment, the disclosure relates to at least one of the preceding embodiments, wherein the light-emitting device comprises two of the laminated sheets, the light-emitting element being located between the laminated sheets and connected to one of the poly(α, α, α′, α′-tetrafluoro-para-xylylene) layers of each of the laminated sheets.

In the description above, for the purposes of explanation, numerous specific details have been set forth in order to provide a thorough understanding of the embodiments. It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, FIGURE, or description thereof for the purpose of streamlining the disclosure and aiding in the understanding of various inventive aspects, and that one or more features or specific details from one embodiment may be practiced together with one or more features or specific details from another embodiment, where appropriate, in the practice of the disclosure.

While the disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A laminated sheet, comprising:
a polymer layer selected from the group consisting of polyalkylene phthalate, polyalkylene isophthalate, polyalkylene terephthalate, and combinations thereof; and
two poly(α,α,α′,α′-tetrafluoro-para-xylylene) layers respectively connected to two opposite surfaces of said polymer layer.

2. The laminated sheet as claimed in claim 1, wherein said polymer layer is a polyalkylene terephthalate layer.

3. The laminated sheet as claimed in claim 2, wherein said polyalkylene terephthalate layer is a polyethylene terephthalate layer.

4. A solar cell module, comprising:
a laminated sheet including a polymer layer selected from the group consisting of polyalkylene phthalate, polyalkylene isophthalate, polyalkylene terephthalate, and combinations thereof, and two poly(α,α,α′,α′-tetrafluoro-para-xylylene) layers respectively connected to two opposite surfaces of said polymer layer; and
a solar cell connected to one of said poly(α,α,α′,α′-tetrafluoro-para-xylylene) layers.

5. The solar cell module as claimed in claim 4, wherein said polymer layer is polyalkylene terephthalate layer.

6. The solar cell module as claimed in claim 5, wherein said polyalkylene terephthalate layer is a polyethylene terephthalate layer.

7. A light-emitting device, comprising:
at least one laminated sheet including a polymer layer selected from the group consisting of polyalkylene phthalate, polyalkylene isophthalate, polyalkylene terephthalate, and combinations thereof, and two poly(α,α,α′,α′-tetrafluoro-para-xylylene) layers respectively connected to two opposite surfaces of said polymer layer; and
a light-emitting element connected to one of said poly(α,α,α′,α′-tetrafluoro-para-xylylene) layers of said laminated sheet.

8. The light-emitting device as claimed in claim 7, wherein said polymer layer is a polyalkylene terephthalate layer.

9. The light-emitting device as claimed in claim 8, wherein said polyalkylene terephthalate layer is a polyethylene terephthalate layer.

10. The light-emitting device as claimed in claim 7, comprising two of said laminated sheets, said light-emitting element being located between said laminated sheets and connected to one of said poly(α,α,α′,α′-tetrafluoro-para-xylylene) layers of each of said laminated sheets.
